(19) United States
(12) Patent Application Publication
(10) Pub. No.: US 2008/0136027 A1
(43) Pub. Date: Jun. 12, 2008

(54) Method of bonding wire of semiconductor package

(76) Inventors: Tae-ho Moon, Cheonan-si (KR); Sang-young Kim, Cheonan-si (KR); Gil-beag Kim, Cheonan-si (KR); Yong-jin Jung, Cheonan-si (KR)

Correspondence Address: HARNESS, DICKEY & PIERCE, P.L.C., P.O. BOX 8910, RESTON, VA, 20195, US

(21) Appl. No.: 11/979,384

(22) Filed: Nov. 2, 2007

(30) Foreign Application Priority Data
Nov. 2, 2006 (KR) 10-2006-0107943

(51) Int. Cl. H01L 23/488; H01L 21/60

(52) U.S. Cl. 257/738; 438/617; 257/E23.023; 257/E21.509

(57) ABSTRACT

Provided is a method of bonding a wire of a semiconductor package, by which a loop height may be reduced and/or a bonding reliability may be enhanced. In the method, a ball bump may be formed on a bonding pad on a semiconductor chip using a capillary through which a wire may be supplied. The wire may then be cut from the ball bump using the capillary. Subsequently, the capillary may be moved to an interconnection corresponding to the bonding pad of the semiconductor chip to perform stitch bonding of the wire supplied through the capillary on the interconnection. The capillary may again be moved to the ball bump formed on the bonding pad to bond the wire on the ball bump.

### PRIORITY STATEMENT

This application claims the benefit of priority under 35 U.S.C. §119 of Korean Patent Application No. 10-2006-0107943, filed on Nov. 2, 2006, in the Korean Intellectual Property Office, the disclosure of which is incorporated herein in its entirety by reference.

### BACKGROUND

As semiconductor packages are gradually minimized and their thicknesses are reduced, a variety of methods of implementing a short loop height in a wire bonding process have been suggested.

In semiconductor packages having an improved shape, such as chip scale packages (CSPs), the technology for directly connecting a semiconductor chip and an external connection terminal using a solder ball, instead of using wire bonding, has been developed. A method of connecting a bonding pad of a semiconductor chip, a lead of a lead frame or a metallization on a circuit substrate using a wire is highly reliable and can be implemented at low costs, and thus, this method is usually used.

In a conventional method of bonding a wire of a semiconductor package, a ball bump may be formed on a bonding pad that is on a semiconductor chip. A wire may be pressurized from an upward direction onto the ball bump to reduce a loop height, or a folding motion of a capillary may be performed to enhance a connection property. However, in the conventional method of bonding the wire, a problem may occur in that the neck of the ball bump may be damaged, and/or cut, as illustrated in FIG. 1. FIG. 1 is a photograph showing the neck of a ball bump that has been cut due to damage of the neck of the ball bump formed on the bonding pad of a semiconductor chip.

In a conventional method of bonding a wire of a semiconductor package, metal plating may be performed on the surface of a lead of a lead frame, and/or a connection pad of a printed circuit board (PCB). When a wire, which may be formed of gold, is ball-bonded with a gold-plated lead, intermetallic bonding between the lead and the wire may not occur and only mechanical bonding therebetween may occur. Thus, ball lift may occur between the lead and the wire. FIG. 2 is a photograph showing the ball lift (portion ‘A’) that may occur between an interconnection 10 and a ball bump 20.

### SUMMARY

Example embodiments may provide a method of bonding a wire of a semiconductor package, by which a loop height may be reduced. According to an example embodiment, Ball neck damage may be prevented and/or the reliability of bonding an interconnection and a wire may be enhanced.

According to an example embodiment, a method of bonding a wire of a semiconductor package may include forming a ball bump on a bonding pad formed on a semiconductor chip using a capillary through which the wire may be supplied; cutting the wire from the ball bump that may be on the bonding pad using the capillary; moving the capillary to an interconnection corresponding to the bonding pad of the semiconductor chip to perform stitch bonding of the wire supplied through the capillary on the interconnection; and moving the capillary onto the ball bump that may be formed on the bonding pad to bond the wire on the ball bump.

In an example embodiment, the method may include bonding the wire on the ball bump by stitch bonding.

In an example embodiment, the method may include cutting the wire from the ball bump after bonding the wire on the ball bump.

In an example embodiment, one or both cutting of the wire may be performed when the wire is fixed by a wire clamp in the capillary.

In an example embodiment, the method may include rounding an end of the wire before the stitch bonding of the wire on the interconnection.

In an example embodiment, the method may include performing a folding motion with the capillary so that the wire bonded on the interconnection may be folded in the stitch bonding of the wire on the interconnection.

In an example embodiment, the interconnection may be gold-plated on a nickel layer, and in the stitch bonding of the wire on the interconnection, the nickel layer and the wire may contact each other. The interconnection may be a lead of a lead frame or a connection pad of a PCB (printed circuit board).

### BRIEF DESCRIPTION OF THE DRAWINGS

The above and other features and advantages will become more apparent by describing in detail example embodiments with reference to the attached drawings in which:

FIG. 1 is a photograph of a conventional semiconductor package showing the case where the neck of a ball bump has been cut due to damage of the neck of the ball bump formed on a bonding pad of a semiconductor chip;

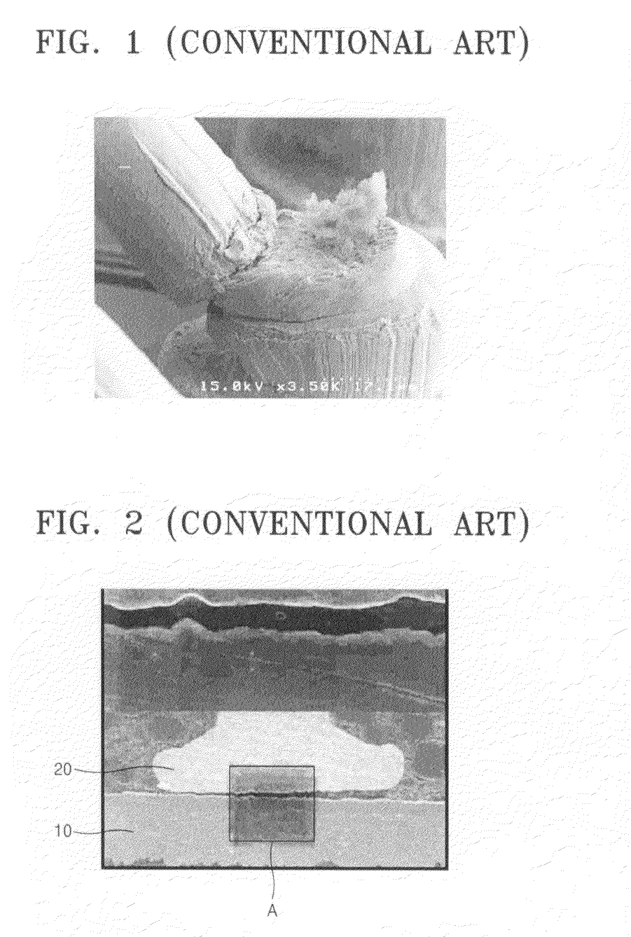

FIG. 2 is a photograph showing a problem of a conventional semiconductor package;

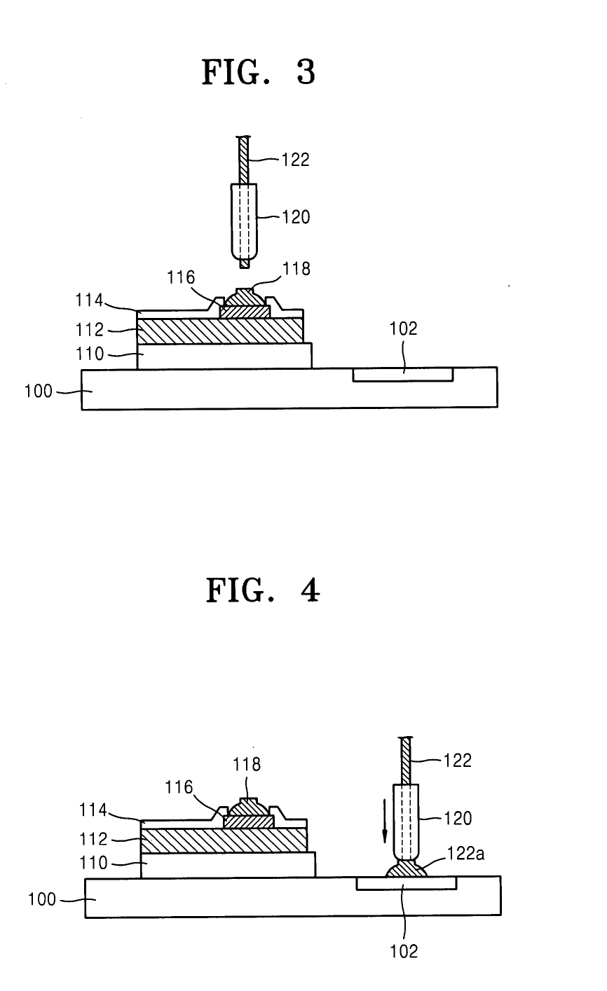

FIGS. 3 through 7 are cross-sectional views illustrating a method of bonding a wire of a semiconductor package, according to an example embodiment; and

FIG. 8 is a photograph showing part of a semiconductor package according to an example embodiment.

### DETAILED DESCRIPTION OF EXAMPLE EMBODIMENTS

Example embodiments will now be described more fully with reference to the accompanying drawings. Example embodiments may, however, be embodied in many different forms and should not be construed as being limited to the example embodiments set forth herein. Rather, example embodiments are provided so that this disclosure will be thorough and complete, and will fully convey the concept of the example embodiments to those skilled in the art. In the drawings, the thicknesses of layers and regions may be exaggerated for clarity. It will also be understood that when a layer is referred to as being “on” another layer or substrate, it may be directly on the other layer or substrate, or intervening layers may also be present. Like reference numerals in the drawings denote like elements, and thus their description will be omitted.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

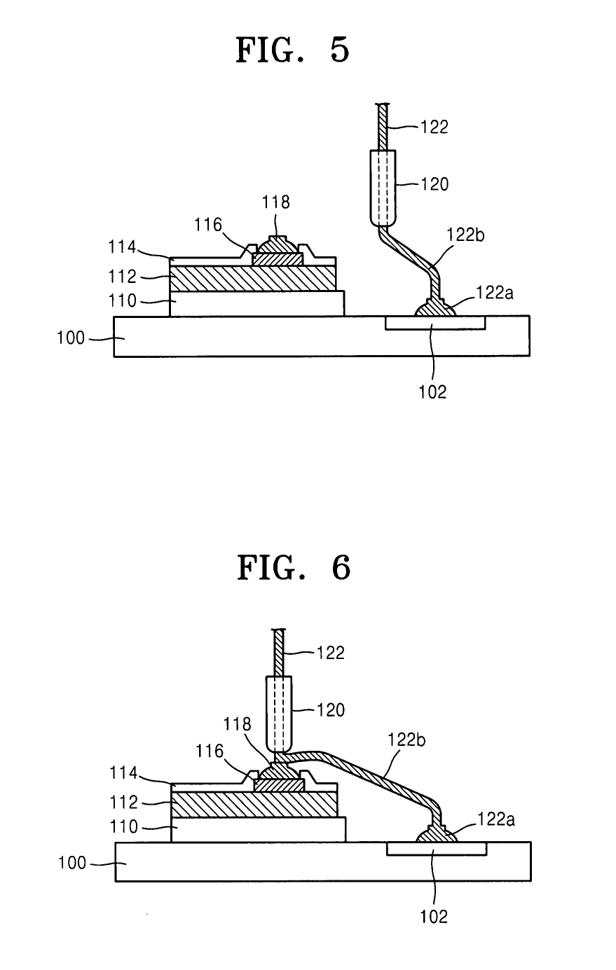

FIGS. 3 through 7 are cross-sectional views illustrating an example embodiment of a method of bonding a wire 122 of a semiconductor package.

The method may involve bonding the wire 122 between a connection pad 102, formed in a predetermined or desired portion of a circuit substrate 100, such as a printed circuit board (PCB), and at least one bonding pad 116, formed on a semiconductor chip 112 attached to a chip pad 110 on the circuit substrate 100. However, the example embodiment is not limited to this, and thus, an example method of bonding a wire between two corresponding connection pads or interconnections that are at least electrically separated from each other and disposed at predetermined or desired intervals may also be applicable.

Referring to FIG. 3, the semiconductor chip 112 adhered to the chip pad 110 may be attached to a predetermined or desired portion of the circuit substrate 100. The bonding pads 116 may be formed in predetermined or desired portions of the semiconductor chip 112, for example, along upper edges of the semiconductor chip 112. To protect a top surface of the semiconductor chip 112, a protection insulating layer 114 may be formed to expose the bonding pads 116 formed on the semiconductor chip 112. The connection pad 102, which may be an external circuit terminal, may be disposed in the portion of the circuit substrate 100. The connection pad 102 may be formed in the portion of the circuit substrate 100 by forming a gold-plated layer on a metal layer, such as a nickel layer.

To bond the wire 122 between the bonding pad 116 and the connection pad 102, a capillary 120 in which the wire 122 is inserted may be moved to the bonding pad 116 of the semiconductor chip 112, and a ball bump 118 may be formed on the bonding pad 116 by the capillary 120 in a wire bonder, which is a piece of bonding equipment.

The capillary 120 that may form the ball bump 118 may cut the wire 122, such as a gold wire, from the ball bump 118 using a wire clamp (not shown) formed in the capillary 120. The wire 122 may be cut using the wire clamp at an upper end of the capillary 120 by sliding the capillary 120 up along the wire 122 when the wire 122 is fixed onto the wire clamp.

Referring to FIG. 4, after the ball bump 118 is formed on the bonding pad 116 and the wire 122 is cut, the capillary 120 with the wire 122 through the capillary 120 may be moved to the connection pad 102. Subsequently, the capillary 120 may slide down the wire 122 in a direction shown by the arrow so that the wire 122 may be bonded to the connection pad 102 using a stitch bonding method (not a ball bonding method). The stitch bonding method may be a method of bonding the wire 122 to the connection pad 102 when the wire 122 has a tail. In an example stitch bonding method, a metal layer of the connection pad 102, such as a nickel layer, may directly contact the wire 122 formed of gold, for example, so that intermetallic bonding between the metal layer of the connection pad 102 and the wire 122 may occur. The stitch bonding method may be performed using a proper load caused by the capillary 120 and ultrasonic vibration. As a result of the stitch bonding, a first connection portion 122a may be formed on the connection pad 102.

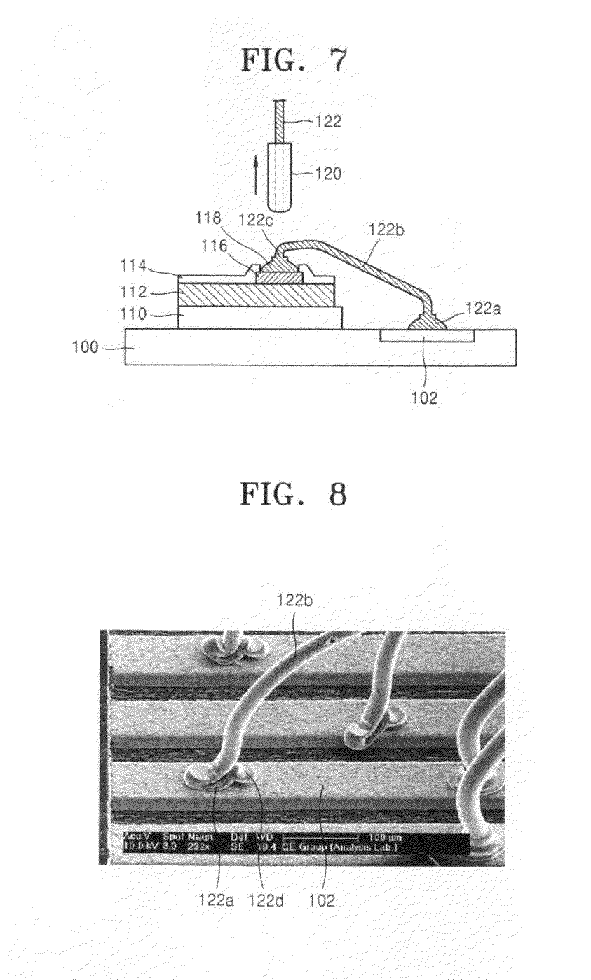

In an example stitch bonding method, a conventional ball bump may not be formed so as to control the length of the tail of the wire 122. However, the end of the wire 122 may be slightly rounded to have a rounded portion 122d at the end of the wire 122 by using a small current from a discharge spark caused by an electrical torch. FIG. 8 shows the ball-shaped portion 122d formed at the end of the wire 122 before the stitch bonding.

The end of the wire 122 that contacts the connection pad 102 may be folded before the stitch bonding. FIG. 8 shows a folded first connection portion 122a. In an example embodiment, the end of the wire 122 may be folded by a folding motion of the capillary 120 having a predetermined or desired track. For example, the end of the wire 122 may be folded by placing the end of the wire 122 to contact the connection pad 102, moving the capillary 120 in a predetermined or desired latitudinal direction, sliding the capillary 120 up along the wire 122, and then moving the capillary 120 in an opposite latitudinal direction and pressurizing the capillary 120.

Referring to FIG. 5, after the first connection portion 122a of the wire 122 is formed on the connection pad 102 using stitch bonding, the capillary 120 may be slid to a predetermined or desired height and may be moved in a direction to the bonding pads 116 so that a wire connection portion 122b having a refractive shape as illustrated in FIG. 5, may be formed in the middle of the wire 122.

Referring to FIG. 6, after the capillary 120 is positioned on the ball bump 118 that has been previously formed on the bonding pads 116, the wire 122 and the ball bump 118 may be bonded at a second connection portion 122c (FIG. 7), using the above-described example stitch bonding method.

Subsequently, as illustrated in FIG. 3, the method of bonding the wire 122 of a semiconductor package may be completed by sliding the capillary 120 along the wire 122, and cutting the wire 122.

Because the stitch bonding may be performed without forming a loop height on the bonding pad 116, the thickness of the semiconductor package may be minimized and/or a problem of damaging the neck of the ball bump 118 may not occur. In addition, because stitch bonding is performed on the connection pad 102, a problem due to ball lift may not occur and/or bonding reliability may be enhanced.

While example embodiments have been particularly shown and described with reference to figures, it will be understood by one skilled in the art that various changes in form and details may be made therein without departing from the spirit and scope of the example embodiments as defined by the following claims. For example, a wire may be an aluminum wire as well as a gold wire, and a bonding pad and a connection pad may have a variety of shapes and may be placed in various positions as to the ones described above, and the example embodiments may also be applied to a stack package in which a plurality of semiconductor chips are stacked in a vertical direction.

What is claimed is:

1. A method of bonding a wire of a semiconductor package, the method comprising:
forming a ball bump on a bonding pad of a semiconductor chip using a capillary through which the wire is supplied;
cutting the wire from the ball bump using the capillary;
moving the capillary to an interconnection corresponding to the bonding pad of the semiconductor chip to perform stitch bonding of the wire supplied through the capillary on the interconnection; and
moving the capillary onto the ball bump that is formed on the bonding pad to bond the wire on the ball bump.

2. The method of claim 1, wherein bonding the wire on the ball bump is performed by stitch bonding.

3. The method of claim 1, further comprising cutting the wire from the ball bump after the bonding of the wire on the ball bump.

4. The method of claim 3, wherein cutting the wire from the ball bump using the capillary and cutting the wire from the ball bump after the bonding of the wire on the ball bump include cutting the wire when the wire is fixed by a wire clamp formed in the capillary.

5. The method of claim 1, further comprising rounding an end of the wire before stitch bonding the wire on the interconnection.

6. The method of claim 1, wherein during stitch bonding of the wire on the interconnection, performing a folding motion with the capillary so that the wire bonded on the interconnection is folded.

7. The method of claim 5, wherein during stitch bonding of the wire on the interconnection, performing a folding motion with the capillary so that the wire bonded on the interconnection is folded.

8. The method of claim 1, wherein the interconnection is gold-plated on a nickel layer, and in the stitch bonding of the wire on the interconnection, the nickel layer and the wire contact each other.

9. The method of claim 1, wherein the interconnection is a lead of a lead frame.

10. The method of claim 9, wherein the interconnection is a connection pad of a PCB (printed circuit board).

11. The method of claim 2, wherein during stitch bonding of the wire on the ball bump, performing a folding motion with the capillary so that the wire bonded on the ball bump is folded.

12. The method of claim 11, further comprising rounding an end of the wire before the stitch bonding of the wire on the ball bump.

13. The method of claim 1, wherein the stitch bonding is performed without forming a loop height on the bonding pad.

14. A semiconductor chip package, comprising:
a circuit substrate having a connection pad;
a semiconductor chip on the circuit substrate, the semiconductor chip having a bonding pad and a ball bump on the bonding pad;
a first connection portion on the connection pad;
a second connection portion on the bonding pad;
a wire between the first connection portion and the second connection portion; and
a first stitch bond at a junction between the wire and the first connection portion and a second stitch bond between the wire and the second connection portion.
